(19) United States
(12) Patent Application Publication
(10) Pub. No.: US 2017/0239728 A1
(43) Pub. Date: Aug. 24, 2017

(54) METHOD FOR CONNECTING COMPONENTS BY PRESSURE SINTERING

(71) Applicant: Heraeus Deutschland GmbH & Co. KG, Hanau (DE)

(72) Inventors: Michael SCHÄFER, Künzell (DE); Wolfgang SCHMITT, Rodgau (DE)

(21) Appl. No.: 15/329,508

(22) PCT Filed: Mar. 18, 2015
(86) PCT No.: PCT/EP2015/055701

§ 371 Date: Jan. 26, 2017

(30) Foreign Application Priority Data
Jul. 28, 2014 (EP) 14178763.0

(51) Int. Cl. B22F 5/00; H01L 23/00; B22F 3/24; C25D 11/34; B22F 3/10; B22F 7/04

(52) U.S. Cl. CPC B22F 5/006; B22F 3/1003; B22F 7/04; B22F 3/24; C25D 11/34; H01L 24/83; H01L 24/32; B22F 2003/242; B22F 2998/10; B22F 2301/255; B22F 2302/25; B22F 2302/45; H01L 2224/8384; H01L 2224/83201; H01L 2224/29186; H01L 2224/29139; H01L 2224/29147; H01L 2224/29164; H01L 2224/83005; H01L 2224/32221

(57) ABSTRACT

A method for connecting components involves providing an arrangement of at least two components each containing at least one metallic contact surface and a metallic sintering agent in the form of a metallic solid body having metal oxide surfaces arranged between the components and pressuring sintering the arrangement whereby metal oxide surfaces of the metallic sintering agent and the metallic contact surfaces of the components each form a joint contact surface. The pressure sintering is carried out in an atmosphere containing at least one oxidizable compound and/or the metal oxide surfaces are provided with at least one oxidizable organic compound before formation of the corresponding joint contact surface.

### CROSS-REFERENCE TO RELATED APPLICATIONS

This application is a Section 371 of International Application No. PCT/EP2015/055701, filed Mar. 18, 2015, which was published in the German language on Feb. 4, 2016 under International Publication No. WO 2016/015878 A1 and the disclosure of which is incorporated herein by reference.

### BACKGROUND OF THE INVENTION

The invention relates to a method for connecting components by pressure sintering involving the use of a metallic sintering agent having metal oxide surfaces.

US 2010/0195292 A1 discloses electronic components having a silver electrode that is provided with an external silver oxide layer. The silver oxide layer can be used for direct connection by sintering of the electronic component to a surface to be connected to it, whereby the silver oxide is reduced to silver.

US 2008/160183 A1 discloses a sintered connection method, in which a composition that can be sintered into a conductive layer and comprises organically coated metal particles and silver oxide particles is used to produce a sintered connection between surfaces that are to be connected. The still sinterable composition can be present in the application form of an ink, a paste or a sintering preform in the form of a layer-shaped pellet.

EP 0 579 911 A2 discloses a method for producing slurry-cast isotropic composite materials based on copper. In this context, a mixed slurry is cast onto a suitable substrate, fired, sintered, and processed through cold-rolling and tempering steps into a massive band. The composite materials can be used for the manufacture of electronic components.

The use of metal sintering pastes or sinterable sinter preforms, produced from them to application and drying, for attachment and electrical contacting of and for heat dissipation from electronic components, such as, for example, semi-conductor chips, is known in the electronics industry. These metal sintering pastes and silver preforms were described, for example, on Jan. 17, 2014 in the online publication “Are Sintered Silver Joints Ready for Use as Interconnect Material in Microelectronic Packaging?” authored by KIM S. SIOW in the Journal of ELECTRONIC MATERIALS (DOI: 10. 1007/s11664-013-2967-3). Examples of patent literature on metal sintering pastes include WO2011/026623A1, EP2425920A1, EP2428293A1, and EP2572814A1. Usually, these metal sintering pastes are applied by printing, for example screen or stencil printing, onto support substrates, dried if needed, configured with electronic components, and then subjected to a sintering process. Without transitioning through the liquid state, the metal particles become connected during the sintering process by diffusion while forming a solid, electrical current- and heat-conducting metallic connection between substrate and electronic component.

### BRIEF SUMMARY OF THE INVENTION

The invention relates to a method for connecting components, comprising providing an arrangement of at least two components each comprising at least one metallic contact surface and a metallic sintering agent in the form of a metallic solid body having metal oxide surfaces arranged between the components, and pressure sintering the arrangement, whereby metal oxide surfaces of the metallic sintering agent and the metallic contact surfaces of the components form a joint contact surface each, and wherein (I) the pressure sintering is carried out in an atmosphere containing at least one oxidizable compound and/or (II) the metal oxide surfaces are provided with at least one oxidizable organic compound before formation of the corresponding joint contact surface.

### DETAILED DESCRIPTION OF THE INVENTION

In the method according to the invention, at least two components are being connected to each other. In this context, an arrangement of at least two components, which each comprise a metallic contact surface, and metallic sintering agent arranged between the components in the form of a metallic solid body having metal oxide surfaces is provided, and this arrangement is sintered in common manner known to a person skilled in the art by applying mechanical pressure and elevated temperature.

The metal oxide surfaces or metal oxide layers referred to hereinafter each are external or outward-facing metal oxide surfaces or metal oxide layers. With respect to the metallic sintering agent disclosed in the following, this can also concern, in particular, a metal oxide surface or metal oxide layer that covers the entire external surface thereof and therefore is outward-facing.

The applicant was able to ascertain that an attachment between components while forming a sintered connection can be attained without, or without direct use of, a metal sintering paste. Surprisingly, a metallic sintering agent having metal oxide surfaces can be used instead of a metal sintering paste.

The wording used herein “whereby metal oxide surfaces of the metallic sintering agent and the metallic contact surfaces of the components form a joint contact surface each” is explicitly meant to include those cases in which only surface fractions of the metal oxide surfaces of the metallic sintering agent and the metallic contact surfaces of the components form a joint contact surface.

Accordingly, embodiment (I) of the method according to the invention comprises the following steps of:
(i) providing at least two components, each having, a metallic contact surface, and a metallic sintering agent in the form of a metallic solid body having metal oxide surfaces;
iii) providing an arrangement of the at least two components and the metallic sintering agent arranged between them while forming joint contact surfaces from the respective metal oxide surface of the metallic sintering agent and the metallic contact surface of the corresponding component; and
(iii) pressure sintering the arrangement in an atmosphere that contains at least one oxidizable compound.

In contrast, embodiment (II) of the method according to the invention comprises the following steps of:
(i) providing at least two components, each with a metallic contact surface, and a metallic sintering agent in the form of a metallic solid body having metal oxide surfaces;
(ii) providing the metal oxide surfaces with at least one oxidizable organic compound;
(iii) providing an arrangement of the at least two components and the metallic sintering agent arranged between them while forming joint contact surfaces from the corresponding metal oxide surface of the metallic sintering agent, which is provided with the at least one oxidizable organic compound, and the metallic contact surface of the corresponding component; and
(iv) pressure sintering the arrangement.

It is feasible to combine embodiments (I) and (II).

Connecting at least two components shall be understood to mean attaching a first component on a second component, in the scope of the present invention “on” shall be understood to simply mean that a metallic contact surface of the first component is being connected to a metallic contact surface of the second component by a metallic sintering agent in the form of a metallic solid body having metal oxide surfaces, in which the relative position of the components or of the arrangement comprising the components is irrelevant.

In the scope of the invention, the term “component” preferably comprises single parts. Preferably, these single parts cannot be disassembled further.

According to specific embodiments, the term “components” refers to parts that are used in electronics. Accordingly, the components can be, for example, active components (e.g., semi-conductor chips, such as LEDs, diodes, IGBTs, thyristors, MOSFETs, transistors, ICs) passive components (e.g., DCBs, leadframes, resistors, capacitors, coils, inductors, memristors, clips, cooling bodies), piezo-ceramics, and Peltier elements.

The components to be connected can be identical or different components.

The components each have one metallic contact surface, in which the metal of the metallic contact surface can be a pure metal or a metal alloy. The alloys comprise, for example, a fraction of >50 wt % of the corresponding metal.

The metals of the metallic contact surfaces of the components to be connected can be identical or different. Preferably, they are selected from the group consisting of silver, copper, palladium, and alloys of these metals. Silver and silver alloys are particularly preferred as metals of the metallic contact surfaces.

The component or components can consist of metal or their metallic contact surface that can be present, for example, in the form of a metallization. This can concern a metallization that is produced, for example, by vapor deposition, chemical galvanization, electroplating, or application from a metal sintering preparation and subsequent sintering. The metal sintering pastes mentioned above are examples of metal sintering preparations.

In the case of a component that does not consist of this metal, the metallic contact surface can be 100 nm to 200 μm in thickness.

Like the metallic sintering agent, the metallic contact surfaces of one component or of all components to be connected can also comprise a metal oxide layer. The metal oxide of this metal oxide layer can be, in particular, an oxide of the metal of the corresponding metallic contact surface.

The metallic sintering agent is a metallic solid body having metal oxide surfaces, i,e., having a total surface or multiple discrete surfaces, each in the form of a metal oxide layer. Accordingly, the metallic sintering agent is a discrete metallic solid body, i.e., it is provided free and/or as a single separate part. Specifically, the metallic sintering agent is present in the shape of a flat or layer-shaped metal part, i.e., as a discrete and/or free metal layer that comprises the metal oxide surfaces. The thickness or layer thickness of the flat or layer-shaped metal part is in the range of, for example, 10 to 300 μm.

The metal of the metallic sintering agent can be pure metal or a metal alloy. The alloys comprise, for example, a fraction of>50 wt. % of the respective metal. Preferably, the metal of the metallic sintering agent is selected from the group consisting of silver, copper, palladium, and alloys of these metals. Silver and silver alloys are particularly preferred as metals.

The metallic sintering agent can just as well be a metal part provided with an external layer made of the same or a different metal, i.e., provided with an external metallization. In this context, the external metallization can be produced, for example, by vapor deposition, chemical galvanization, electroplating, or application from a metal sintering preparation and subsequent sintering. The metal sintering pastes mentioned above are examples of metal sintering preparations that can be used in this context.

In one embodiment, the metallic sintering agent is a layer-shaped metal sintering body, i.e., a sintered metal structure in the form of a layer, in other words, a metal structure that cannot be sintered any longer as such. A sintered metal structure of this type comprises, in particular, no metal oxide, i.e., no metal oxide in its mass, other than the external metal oxide surfaces mentioned above. A sintered layer-shaped metal sintering body of this type shall not be mistaken for one of the still sinterable sintering preforms mentioned above. The metallic sintering agent in the shape of a layer-shaped metal sintering body can be produced by application, for example, by screen printing, stencil printing or spray application, from a metal sintering preparation onto a support substrate having a surface that is incapable of forming a sintered connection, followed by sintering of the metal sintering preparation thus applied while applying, or preferably not applying, mechanical pressure, followed by detachment of the layer-shaped metal sintering body thus formed from the surface of the support substrate. If no of only an insufficient metal oxide layer is generated on the surface of the layer-shaped metal, sintering body after this sequence of production steps, for example by atmospheric oxidation, a downstream oxidation step can be added for the purpose of producing or reinforcing a metal oxide layer on the entire external surface or on parts of the external surface of the layer-shaped metal sintering body. Oxidation processes as illustrated below can be used in this context.

The metal sintering pastes mentioned above are examples of metal sintering preparations that can be used in the production of a layer-shaped metal sintering body of this type

Suitable support substrates having a surface that is incapable of forming a sintered connection for use in the production of the layer-shaped metal sintering bodies include, for example, aluminum oxide ceramics, nickel foils, polyimide films, polytetrafluoroethylene films, and silicone films. It is obvious to a person skilled in the art to select planar support substrates having a non-porous and sufficiently smooth surface in this context, regardless of the selection of material.

The application of the metal sintering preparation, for example screen printing, stencil printing or spray application, as well as the procedure of sintering are well-known to a person skilled in the art and there are no method-related particularities such that a detailed description is not required and reference shall be made in this context, for exemplary purposes, to the literature cited above. Likewise, the detachment from the support substrate having a surface that is incapable of forming a sintered connection bears no difficulty since the layer-shaped metal sintering body thus formed basically detaches by itself during the sintering process.

The metallic sintering agent, in particular in the form of the layer-shaped metal sintering body, can be produced in the format desired by the operator of the method according to the invention such that no waste arises in the form of clippings at the premises of said operator. It can also be expedient to produce the metallic sintering agent, in particular in the form of the layer-shaped metal sintering body, as endless ware and to deliver it to the operator of the method, for example, still situated on the support substrate or already detached from the support substrate. Endless ware can be provided with pre-determined breakage sites, for example with perforations, to be easy and according to specifications to use by the operator of the method. In the case of endless ware, reeled goods are the preferred delivery form.

In any case, the metallic sintering agent comprises these metal oxide surfaces, which can each form a joint contact surface with the metallic contact surfaces of the components. In this context, the metal oxide surfaces that are capable of forming joint contact surfaces with the metallic contact surfaces of the components can be present as discrete metal oxide surfaces, i.e., delimited from each other. However, they can just as well be present in the form of a continuous metal oxide layer covering part or all of the surface of the metallic sintering agent. Referring to the metallic sintering agent in the shape of a flat or layer-shaped metal part, the metal oxide surfaces are preferably situated on the front and rear side thereof such that the arrangement produced in the method according to the invention has a sandwich structure, i.e., the components of the arrangement of the components with metallic sintering agent arranged in between are then situated on opposite sides of the metallic sintering agent.

The metal oxide of the metal oxide layer or of the discrete metal oxide surfaces of the metallic sintering agent can be, in particular, an oxide of the metal of the metallic sintering agent or an oxide of the metal of an external metallization of the metallic sintering agent. The external or outward-facing metal oxide layer is firmly connected to the metal situated underneath. The layer can be, for example, 0.02 to 6 μm in thickness. It can be formed by oxidation, in particular by oxidation of the corresponding metal, upon contact with air or it can be produced or reinforced chemically by oxidation agents or by anodic oxidation of the metallic surface that is not, not yet, only a little, or more or less oxidized. As indicated in the preceding sentence, a pre-existing thin layer of the metal oxide can be generated or reinforced, for example, by anodic oxidation. For example, a non-oxidized, partly-oxidized or initially-oxidized metal surface can be oxidized by anodic oxidation up to the formation of a metal oxide layer that is, for example, 0.03 to 5 μm thick. Referring to a silver surface, a silver oxide layer with a layer thickness of, for example, 0.05 to 1 μm, can be formed by anodic oxidation.

The anodic oxidation can be implemented, for example, by immersing the metallic sintering agent, arranged as anode and to be oxidized on its surface, in a suitable aqueous electrolyte solution. Suitable aqueous electrolyte solutions include, for example, 5 to 10 wt. % aqueous solutions of sodium carbonate, sodium hydrogen carbonate, potassium hydroxide or sodium hydroxide. The anodic oxidation can take place, for example, for 5 to 30 seconds at a direct voltage in the range of 5 to 20 volts.

In the method according to the invention, components are connected to each other by pressure sintering by a metallic sintering agent, in the form of the metallic solid body having metal oxide surfaces, being arranged between them, i.e., the components and the metallic sintering agent situated between them are connected to each other by heating and by applying mechanical pressure without the metals of the metallic contact surfaces of the components and of the metallic sintering agent transitioning into the liquid phase.

In embodiment (I) of the method according to the invention, the pressure sintering takes place in an atmosphere that contains at least one oxidizable compound. Examples of suitable oxidizable compounds include carbon monoxide, hydrogen, and formic acid. The atmosphere can consist of the at least one oxidizable and gaseous compound or it can contain the latter in combination with inert gases such as, in particular, nitrogen and/or argon. Preferably, the fraction of oxidizable compounds in the atmosphere is 1 to 30 vol. %.

In embodiment (II) of the method according to the invention, the metal oxide surfaces of the metallic sintering agent and—if the metallic contact surface of at least one of the at least two components comprises a metal oxide layer—preferably the latter as well is/are being provided with at least one organic compound, i.e., with one or a mixture of two or more oxidizable organic compounds, before forming the joint contact surface.

The oxidizable organic compounds preferably comprise 1 to 50, more preferably 2 to 24, even more preferably 6 to 24 and yet more preferably 8 to 20 carbon atoms and have at least one functional group.

It is preferable to use free fatty acids, fatty acid salts or fatty acid esters as oxidizable organic compounds. The free fatty acids, fatty acid salts, and fatty acid esters preferably are non-branched. Moreover, the free fatty acids, fatty acid salts, and fatty acid esters preferably are saturated.

Preferred fatty acid salts include the ammonium, monoalkylammonium, dialkylammonium, trialkylammonium, aluminum, copper, lithium, sodium, and potassium salts.

Alkyl esters, in particular methyl esters, ethyl esters, propyl esters, and butyl esters, are preferred esters.

According to a preferred embodiment, the free fatty acids, fatty acid salts or fatty acid esters are compounds with 8 to 24, more preferably 8 to 18, carbon atoms.

Preferred oxidizable organic compounds include caprylic acid (octanoic acid), capric acid (decanoic acid), lauric acid (dodecanoic acid), myristic acid (tetradecanoic acid), palmitic acid (hexadecanoic acid), margaric acid (heptadecanoic acid), stearic acid (octadecanoic acid), arachinic acid (eicosanoic acid/icosanoic acid), behenic acid (docosanoic acid), lignoceric acid (tetracosanoic acid) as well as the corresponding esters and salts.

Particularly preferred oxidizable organic compounds include dodecanoic acid, octadecanoic acid, aluminum stearate, copper stearate, sodium stearate, potassium stearate, sodium palmitate, and potassium palmitate.

In order to provide the corresponding metal oxide layer with the at least one oxidizable organic compound, the latter can, for example, be applied to the surface of the metal oxide layer as the effective substance without diluting or can be applied from an aqueous preparation or from a preparation in an organic solvent, followed by drying, for example at an object temperature of 15 to 50° C. for a drying period of 10 to 60 minutes. In terms of the mode of application, there is basically no restriction, for example the metal oxide layer can be dipped into the preparation of the at least one oxidizable organic compound or the preparation of the at least one oxidizable organic compound can be sprayed or painted onto the metal oxide layer. The aqueous preparation or the organic solvent-based preparation can be, for example, a 1 to 20 wt. % solution, dispersion or suspension of the at least one oxidizable organic compound.

The ratio of the mass of the at least one oxidizable organic compound to the surface area of the metal oxide layer provided or to be provided with the at least one oxidizable organic compound is, for example, 0.0005 to 10 g of the at least one oxidizable organic compound per square-meter of metal oxide surface. A person skilled in the art will select this ratio based on the thickness of the metal oxide layer, i.e., the higher the thickness of the metal oxide layer, the higher the person skilled in the art will select the ratio of the mass of the at least one oxidizable organic compound to the surface area of the metal oxide layer to be provided with the at least one oxidizable organic compound.

For production of the joint contact surfaces, the components are placed, each by their metallic contact surface, onto the corresponding metal oxide surfaces of the metallic sintering agent that are provided with the at least one oxidizable organic compound. The region of overlap of the metallic contact surfaces or surface fractions thereof and the corresponding metal oxide surface defines the joint contact surface in this context.

Finally, the arrangement of the at least two components and the metallic sintering agent situated in between them, which comprises the metal oxide surfaces provided with the at least one oxidizable organic compound, is subjected to a pressure sintering process.

The actual pressure sintering takes place at an object temperature of, for example, 200 to 280° C. and the process pressure is in the range, for example, of 1 to less than 40 MPa, preferably 5 to 20 MPa. The sintering time is in the range of, for example, 1 to 5 minutes.

If the procedure follows embodiment (II) of the method according to the invention exclusively, the pressure sintering can take place in an atmosphere that is not subject to any special restrictions except that it is different from the atmosphere prevailing in embodiment (I). For example, an atmosphere containing oxygen or an oxygen-free atmosphere can prevail in embodiment (II). In the scope of the invention, an oxygen-free atmosphere shall be understood to mean an atmosphere, in particular an inert gas atmosphere, for example of nitrogen and/or argon, whose oxygen content is no more than 500 ppm, preferably no more than 10 ppm, and even more preferably no more than 1 ppm.

The pressure sintering takes place in a conventional apparatus that is suitable for pressure sintering, in which the above-mentioned process parameters can be set.

### Exemplary Embodiment 1

Stencil printing was used to apply a layer of a silver sintering paste (ASP 043-04P2 from Heraeus Materials Technology) sized 10×10 mm² onto a support substrate in the form of a polytetrafluoroethylene film at a wet layer thickness of 100 μm, which was then sintered for 30 min in a circulating-air drying cabinet at an object temperature of 250° C.

The sintered product was carefully detached from the support substrate using a suction pipette to obtain a free layer-shaped silver sintering body.

A 10 wt. % aqueous sodium carbonate solution was placed in a stainless steel vessel and the stainless steel vessel was connected to the cathode of a 10 V direct voltage source. The anode of the voltage source was connected to the free layer-shaped silver sintering body and the latter was then immersed in the sodium carbonate solution for 30 seconds.

Once it was taken out, the blackened surface of the free layer-shaped silver sintering body resulting from anodic oxidation was rinsed with deionized water and then dried. Subsequently, one droplet of a 2 wt. % lauric acid solution in Exxsol D60 was placed on the silver oxide surfaces on the front and rear side, distributed evenly, and dried in a circulating-air heating cabinet at 70° C. Then the silver sintering body thus provided with lauric acid was joined between the gold surface of a corresponding DCB substrate and the silver contact surface of an IGBT sized 10×10 min² and the sandwich arrangement thus produced was sintered in a sintering press for 120 seconds at an object temperature of 250° C. and a mechanical pressure of 20 MPa.

### Exemplary Embodiment 2

A 10 wt. % aqueous sodium carbonate solution was placed in a stainless steel vessel and the stainless steel vessel was connected to the cathode of a 10 V direct voltage source. The anode of the voltage source was connected to a silver band 3 cm in length, 3 mm in width, and 0.1 mm in thickness from Schlenk Metailfolien and the latter was immersed in the sodium carbonate solution for 30 seconds.

Once it was taken out, the blackened silver surface resulting from anodic oxidation was rinsed with deionized water and the silver hand was dried. Subsequently, the anodically oxidized silver band was immersed in a 2 wt. % lauric acid solution in Exxsol D60 and, after taking it out, dried at 70° C. in a circulating-air drying cabinet. Then the silver band thus prepared was joined between the silver-plated contact surface of a copper leadframe and the silver contact surface of an Si chip sized 2×2 mm² and the sandwich arrangement thus produced was sintered in a sintering press for 120 seconds at an object temperature of 250° C. and a mechanical pressure of 20 MPa.

After the sintering, the bonding was determined by testing the shear strength. In this context, the components were sheared off with a shearing chisel at a rate of 0.3 mm/s at 20° C. The force was measured by means of a load cell (DAGE 2000 device made by DAGE, Germany). Table 1 shows the results obtained with examples 1 to 2.

TABLE 1

Example

| | 1 | 2 |
|---|---|---|
| Shear strength | 31 | 40 |
| (N/mm²) | | |

It will be appreciated by those skilled in the art that changes could be made to the embodiments described above without departing from the broad inventive concept thereof. It is understood, therefore, that this invention is not limited to the particular embodiments disclosed, but it is intended to cover modifications within the spirit and scope of the present invention as defined by the appended claims.

1.-18. (canceled)

19. A method for connecting components comprising providing an arrangement of at least two components each comprising at least one metallic contact surface and a metallic sintering agent in the form of a metallic solid body having metal oxide surfaces arranged between the components, and pressuring sintering the arrangement, whereby the metal oxide surfaces of the metallic sintering agent and the metallic contact surfaces of the components each form a joint contact surface, and wherein (I) the pressure sintering is carried out in an atmosphere containing at least one oxidizable compound and/or (II) the metal oxide surfaces are provided with at least one oxidizable organic compound before formation of the corresponding joint contact surface.

20. The method according to claim 19, wherein the metallic solid body is a flat or layer-shaped metal part having a thickness or layer thickness is in a range of 10 to 300 μm.

21. The method according to claim 19, wherein the metal of the metallic sintering agent is selected from the group consisting of silver, copper, palladium, and alloys thereof.

22. The method according to claim 20, wherein the metal part is a layer-shaped metal sintering body obtained by a method comprising:
(1) applying a metal sintering preparation onto a support substrate having a surface that, is incapable of forming a sintered connection;
(2) sintering the applied metal sintering preparation;
(3) detaching the layer-shaped metal sintering body formed in step (2) from the surface of the support substrate; and
(4) optionally producing or reinforcing a metal oxide layer on at least a part of the external surface of the layer-shaped metal sintering body by an oxidation step after step (3).

23. The method according to claim 22, wherein the support substrate is selected from the group consisting of aluminum oxide ceramics, nickel foils, polyimide films, polytetrafluoroethylene films, and silicone films.

24. The method according to claim 19, wherein the metallic sintering agent comprises a front and a rear side on which metal oxide surfaces are situated.

25. The method according to claim 19, wherein the metal oxide is an oxide of the metal of the metallic sintering agent or an oxide of the metal of an external metallization of the metallic sintering agent.

26. The method according to claim 19, wherein the metal oxide layer or metal oxide surface is formed by contact with air or is produced or reinforced chemically by oxidation, agents or by anodic oxidation.

27. The method according to claim 19, wherein the components are used in electronics.

28. The method according to claim 19, wherein the metals of the metallic contact surfaces of the components to be connected are identical or different and are selected from the group consisting, of silver, copper, palladium, and alloys thereof.

29. The method according to claim 19, wherein the metallic contact surface of at least one of the at least two components comprises a metal oxide layer.

30. The method according to, claim 29, wherein the metal oxide layer is provided with at least one oxidizable organic compound before forming the joint contact surface.

31. The method according to claim 19, wherein the at least one oxidizable organic compounds comprises 1 to 50 carbon atoms and has at least one functional group.

32. The method according to claim 19, wherein the ratio of the mass of the at least one oxidizable organic compound to the surface area of the corresponding metal oxide layer is 0.0005 to 10 g per square-meter of metal oxide surface.

33. The method according to claim 19, wherein the at least one oxidizable organic compound is selected from free fatty acids, fatty acid salts, and fatty acid esters,

34. The method according to claim 19, wherein the at least one oxidizable organic compound is applied to the metal oxide layer from an aqueous preparation or from a preparation in organic solvent.

35. The method according to claim 34, wherein the preparation is a solution, dispersion or suspension.

36. A connection of components produced according to the method of claim 19.
